(19) United States
(12) Patent Application Publication
(10) Pub. No.: US 2005/0024890 A1
(43) Pub. Date: Feb. 3, 2005

(54) Light guide plate, surface light-emitting unit, and liquid crystal display device and method for manufacturing the same

(75) Inventors: Koichi Yamamoto, Fukushima-ken (JP); Hideaki Nagakubo, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 10/865,385

(22) Filed: Jun. 10, 2004

(30) Foreign Application Priority Data
Jun. 19, 2003 (JP) 2003-174858
Jun. 19, 2003 (JP) 2003-174859

(51) Int. Cl. H01L 33/00; F21V 7/04; G02F 1/1335

(52) U.S. Cl. 362/555; 349/63

(57) ABSTRACT

A liquid crystal display device includes a liquid crystal display panel having a display surface, and a surface light-emitting unit on the display surface consisting of a light source and a light guide plate for introducing light emitted from the light source into the interior of the light guide plate and emitting the light from an exit surface thereof, wherein at least the exit surface is formed from a resilient material and the exit surface is in tight contact with the display surface of the liquid crystal display panel.

### BACKGROUND OF THE INVENTION

1. Field of the Invention

The present invention relates to a light guide plate, a surface light-emitting unit, and a liquid crystal display device and a method for manufacturing the liquid crystal display device.

2. Description of the Related Art

A front light is an efficient and superior surface-emitting light source that has been used for illumination of liquid crystal display panels. In general, a front light (surface light-emitting unit) includes a light source and a light guide plate. The light guide plate is usually disposed on the viewing side of a liquid crystal display panel, with an air layer therebetween, to illuminate the liquid crystal display panel.

Unfortunately, light is reflected from the air layer between the light guide plate and the liquid crystal display panel. The reflected light disadvantageously decreases the contrast of the panel and therefore considerably decreases viewability. That is, the light emitted from the light source propagates inside the light guide plate and is output from an exit surface of the light guide plate into the air layer. The liquid crystal display panel is then irradiated with the output light. However, part of the light is reflected at the interface between the exit surface of the light guide plate and the air layer. The reflected light increases the brightness of a black display. Accordingly, the contrast, which is the luminance ratio of a white display to a black display, is disadvantageously decreased.

Additionally, tight contact between the light guide plate and the liquid crystal display panel is difficult due to slight warpage of the glass substrates thereof.

Japanese Unexamined Patent Application Publication No. 11-326903 discloses a liquid crystal display device that improves the contrast by having an adhesive layer between a light guide plate and a liquid crystal display panel.

However, in the liquid crystal display device disclosed in that publication, there is a possibility that light is reflected at both interfaces between the light guide plate and the adhesive layer, and between the adhesive layer and the liquid crystal display panel. Therefore, this is no ideal solution for increasing the contrast.

Also, the liquid crystal display device disclosed in that publication employs a single adhesive layer. This requires a certain thickness of the adhesive layer, thus sometimes causing bubbles in the adhesive layer. Consequently, tight contact between the light guide plate and the liquid crystal display panel is difficult.

### SUMMARY OF THE INVENTION

Accordingly, it is an object of the present invention to provide a light guide plate, a surface light-emitting unit, and a liquid crystal display device and a method for manufacturing the liquid crystal display device in which the contrast is increased.

A light guide plate according to the present invention includes a plate member, a reflecting surface on one side of the plate member for reflecting light propagating inside the plate member, and an exit surface on the other side of the plate member for outputting the light reflected by the reflecting surface. At least the exit surface is formed from a resilient material.

According to the above-described structure, since the exit surface is formed from a resilient material, the exit surface can be in tight contact with a liquid crystal display panel. Accordingly, there is no possibility that light is reflected at an interface between the light guide plate and the liquid crystal display panel, thus increasing the contrast.

In the light guide plate according to the present invention, the entire plate member is preferably made of a resilient material.

Additionally, the plate member of the light guide plate may be made from a laminate of a resilient material and a hard material, the exit surface may be disposed on the resilient material side, and the reflecting surface may be disposed on the hard material side.

In either above-described case, since the exit surface is formed from a resilient material, the exit surface can be in tight contact with the liquid crystal display panel. Accordingly, reflected light can be prevented at the interface between the light guide plate and the liquid crystal display panel, thus increasing the contrast.

Additionally, in this light guide plate, since the hard material is layered on the resilient material, the hard material functions as a reinforcing material. This facilitates handling of the light guide plate and, therefore, the light guide plate can be easily in tight contact with the liquid crystal display panel.

In the above-described light guide plate according to the present invention, the reflecting surface has a series of grooves in the propagation direction of the light, each groove has a gentle slope inclined towards the propagation direction of the light and a steep slope which is inclined towards the opposite propagation direction of the light and which has a larger slope angle than that of the gentle slope, the slope angle θ₁ of the gentle slope ranges from 1° to 5°, the slope angle θ₂ of the steep slope ranges from 40° to 45°, and the pitch of the grooves ranges from 50 μm to 300 μm.

These ranges of the slope angles θ₁ and θ₂ and the pitch can further increase the contrast.

A surface light-emitting unit according to the present invention includes any one of the light guide plates described above, and a light source disposed on a side surface of the light guide plate for emitting light into the interior of the light guide plate through the side surface. In this structure, since the exit surface is formed from a resilient material, the exit surface can be in tight contact with the liquid crystal display panel without any gaps. Accordingly, there is no possibility that light is reflected at an interface between the light guide plate and the liquid crystal display panel, thus increasing the contrast.

Further, a liquid crystal display device according to the present invention includes a liquid crystal display panel having a display surface, and a surface light-emitting unit on the display surface including a light source and a light guide plate for introducing light emitted from the light source into the interior of the light guide plate and outputting the light from an exit surface thereof. At least the exit surface is formed from a resilient material and the exit surface is in tight contact with the display surface of the liquid crystal display panel.

In this structure, since the exit surface is formed from a resilient material, the exit surface can be in tight contact with the liquid crystal display panel without any gaps. Accordingly, there is no possibility that light is reflected at an interface between the light guide plate and the liquid crystal display panel, thus increasing the contrast.

Preferably, in the liquid crystal display device according to the present invention, the light guide plate has a reflecting surface for reflecting light propagating inside the light guide plate and an exit surface opposite to the reflecting surface for outputting the light reflected by the reflecting surface.

Preferably, in the liquid crystal display device according to the present invention, the entire light guide plate is formed from a resilient material.

Additionally, in the liquid crystal display device according to the present invention, the light guide plate may be formed from a laminate of a resilient material and a hard material, the exit surface may be disposed on the resilient material side, and the reflecting surface may be disposed on the hard material side.

In either case described above, since the exit surface is formed from a resilient material, the exit surface can be in tight contact with the liquid crystal display panel without any gaps. Accordingly, reflected light can be prevented at the interface between the light guide plate and the liquid crystal display panel, thus increasing the contrast.

In the above-described liquid crystal display device according to the present invention, the reflecting surface has a series of grooves in the propagation direction of the light, each groove has a gentle slope inclined towards the propagation direction of the light and a steep slope which is inclined towards the opposite propagation direction of the light and which has a larger slope angle than that of the gentle slope, the slope angle θ₁ of the gentle slope ranges from 1° to 5°, the slope angle θ₂ of the steep slope ranges from 40° to 45°, and the pitch of the grooves ranges from 50 μm to 300 μm.

These ranges of the slope angles θ₁ and θ₂ and the pitch can further increase the contrast.

A liquid crystal display device according to the present invention includes a liquid crystal display panel having a display surface, and a surface light-emitting unit on the display surface including a light source and a light guide plate for introducing light emitted from the light source into the interior of the light guide plate and outputting the light from an exit surface thereof. The exit surface is in tight contact with the display surface by an adhesive layer, and the adhesive layer includes an adhesive transparent resin film layered on the exit surface, another adhesive transparent resin film layered on the display surface, and an ultraviolet-curable resin layer between the adhesive transparent resin films.

In the above-described liquid crystal display device, since the exit surface is in tight contact with the display surface by an adhesive layer including the adhesive transparent resin films and the ultraviolet-curable resin layer, each resin film of the adhesive layer can be relatively thin and, therefore, bubbles do not occur in the layers. Accordingly, there is no possibility that light is reflected at an interface between the light guide plate and the liquid crystal display panel, thus increasing the contrast.

In the above-described liquid crystal display device, at least the exit surface of the light guide plate is formed from a resilient material. In this structure, the exit surface can be in tight contact with the liquid crystal display panel without any gaps. Accordingly, reflected light can be prevented at the interface between the light guide plate and the liquid crystal display panel, thus increasing the contrast.

Preferably, a material for the adhesive transparent resin films is acrylate adhesive transparent resin. Further, the thickness of each adhesive transparent resin film preferably ranges from about 100 μm to 400 μm.

Furthermore, a material used for the ultraviolet curable resin layer is preferably acrylate UV-curable resin. The thickness of the ultraviolet curable resin layer is preferably smaller than or equal to about 100 μm.

Preferably, in the liquid crystal display device according to the present invention, the light guide plate has a reflecting surface for reflecting light propagating inside the light guide plate and an exit surface opposite to the reflecting surface for outputting the light reflected by the reflecting surface.

Additionally, in the liquid crystal display device according to the present invention, the entire light guide plate is preferably formed from a resilient material.

Further, in the liquid crystal display device according to the present invention, the light guide plate may be formed from a laminate of a resilient material and a hard material, the exit surface may be disposed on the resilient material side, and the reflecting surface may be disposed on the hard material side.

In either case described above, since the exit surface is formed from a resilient material, the exit surface can be in tight contact with the liquid crystal display panel without any gaps. Accordingly, reflected light can be prevented at the interface between the light guide plate and the liquid crystal display panel, thus increasing the contrast.

Additionally, in the light guide plate, since the hard material is layered on the resilient material, the hard material functions as a reinforcing material. This facilitates handling of the light guide plate and, therefore, the light guide plate can be easily in tight contact with the liquid crystal display panel.

In the above-described light guide plate according to the present invention, the reflecting surface has a series of grooves in the propagation direction of the light, each groove has a gentle slope inclined towards the propagation direction of the light and a steep slope which is inclined towards the opposite propagation direction of the light and which has a larger slope angle than that of the gentle slope, the slope angle θ₁ of the gentle slope ranges from 1° to 5°, the slope angle θ₂ of the steep slope ranges from 40° to 45°, and the pitch of the grooves ranges from 50 μm to 300 μm.

These ranges of the slope angles θ₁ and θ₂ and the pitch can further increase the contrast.

According to the present invention, in a method for attaching a surface light-emitting unit to a liquid crystal display panel, the surface light-emitting unit includes a light source and a light guide plate having an exit surface for outputting light emitted from the light source and introduced into the interior of the light guide plate. The method includes the steps of: forming an adhesive transparent resin film on the exit surface; forming another adhesive transparent resin film on a display surface of the liquid crystal display panel; applying a fluid uncured-ultraviolet curable resin to at least one surface of the adhesive transparent resin films to form a uncured-ultraviolet curable resin layer; bonding the exit surface to the display surface with the adhesive transparent resin films and the ultraviolet curable resin layer between the adhesive transparent resin films; and curing the ultraviolet curable resin layer by irradiating the ultraviolet curable resin layer through the light guide plate with ultraviolet rays.

Since the surface light-emitting unit is bonded to the liquid crystal display panel after a fluid ultraviolet curable resin is applied to at least one surface of the adhesive transparent resin films, the ultraviolet curable resin spreads over the entire surfaces of the adhesive transparent resin films so that bubbles are completely expelled from between the surface light-emitting unit and the liquid crystal display panel. Consequently, the light guide plate of the surface light-emitting unit can be easily brought into tight contact with the liquid crystal display panel without bubbles remaining in the interior of the adhesive layer by irradiating the ultraviolet curable resin with ultraviolet rays.

### BRIEF DESCRIPTION OF THE DRAWINGS

FIG. 1 is a perspective view of a liquid crystal display device according to a first embodiment of the present invention;

FIG. 2 is a schematic sectional view taken along a line II-II in FIG. 1;

FIG. 3 is an enlarged schematic sectional view of a relevant portion of the liquid crystal display device shown in FIG. 2;

FIG. 4 is a schematic sectional view of a liquid crystal display device according to a second embodiment of the present invention;

FIG. 5 is an enlarged schematic sectional view of a relevant portion of the liquid crystal display device shown in FIG. 4;

FIG. 6 is a schematic sectional view of a liquid crystal display device according to a third embodiment of the present invention;

FIG. 7 is an enlarged schematic sectional view of a relevant portion of the liquid crystal display device shown in FIG. 6;

FIG. 8 is a schematic sectional view of a liquid crystal display device according to a fourth embodiment of the present invention;

FIG. 9 is an enlarged schematic sectional view of a relevant portion of the liquid crystal display device shown in FIG. 8;

FIG. 10 is a cross-sectional view of a liquid crystal display device in a fabrication step according to a fifth embodiment of the present invention;

FIG. 11 is a cross-sectional view of the liquid crystal display device in a fabrication step according to the fifth embodiment of the present invention;

FIG. 12 is a cross-sectional view of the liquid crystal display device in a fabrication step according to the fifth embodiment of the present invention; and

FIG. 13 is a cross-sectional view of the liquid crystal display device in a fabrication step according to the fifth embodiment of the present invention.

### DESCRIPTION OF THE PREFERRED EMBODIMENTS

### First Embodiment

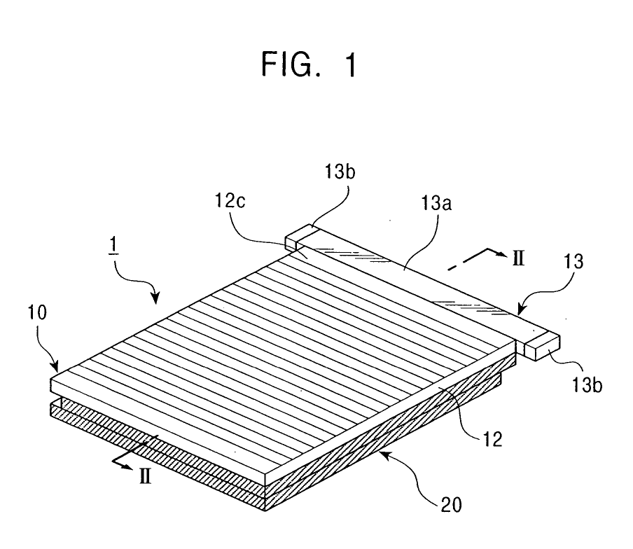

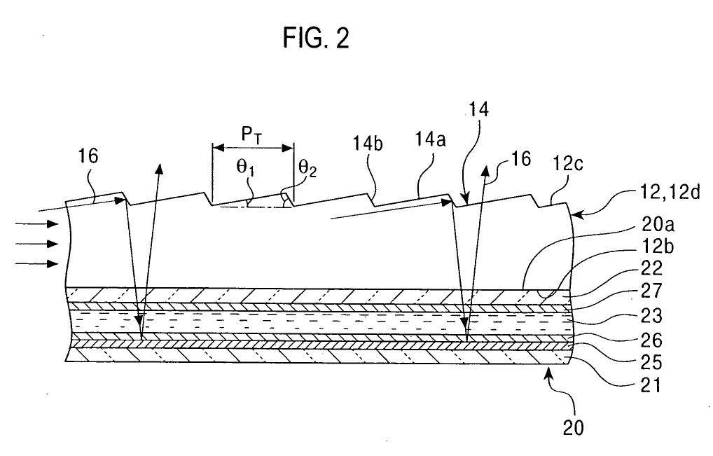

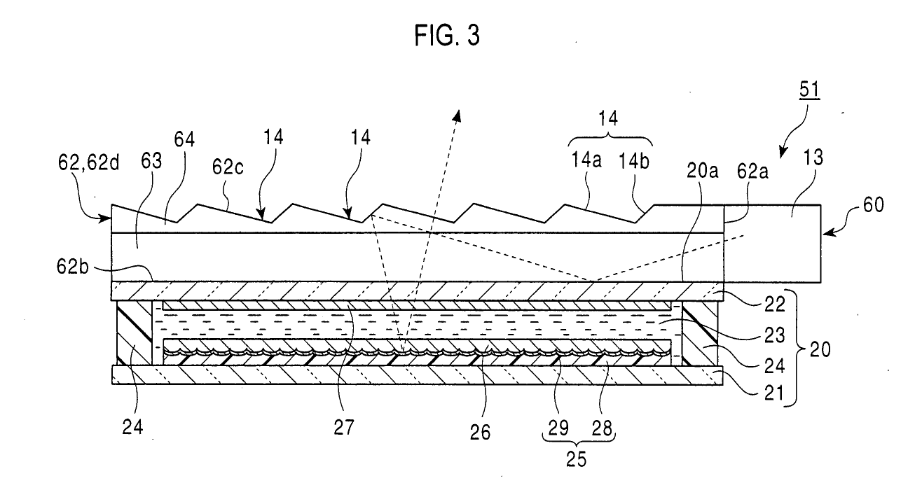

A first embodiment of the present invention will now be described with reference to the accompanying drawings. FIG. 1 is a perspective view of a liquid crystal display device according to the embodiment. FIG. 2 is a schematic sectional view taken along a line II-II in FIG. 1. FIG. 3 is an enlarged schematic sectional view of a relevant portion of the liquid crystal display device shown in FIG. 2. FIGS. 1 to 3 are drawings only for explaining the structure of the liquid crystal display device and, therefore, the scales for the dimensions and thicknesses of the elements are different from the actual ones.

As shown in FIGS. 1 and 2, a liquid crystal display device I according to the embodiment includes a liquid crystal display panel 20 and a front light (surface light-emitting unit) 10, which is disposed on the display surface 20a of the liquid crystal display panel 20 to illuminate the liquid crystal display panel 20. The front light 10 includes a transparent light guide plate 12 and a light source 13. The light source 13 is mounted on a side surface 12a of the light guide plate 12, and light enters the light guide plate 12 from the side surface 12a. The light guide plate 12 is made of a resilient material. An exit surface 12b of the light guide plate 12 is in tight contact with the display surface 20a of the liquid crystal display panel 20.

The liquid crystal display panel 20 includes a first glass substrate 21 and a second glass substrate 22 opposing each other with a liquid crystal layer 23 therebetween. The first and second substrates 21 and 22 are bonded with a seal 24 to form the liquid crystal display panel 20. On the surface of the first substrate 21 facing the liquid crystal layer 23, a reflecting layer (reflector) 25, which consists of an organic film 28 and a metal reflecting film 29 thereon to reflect incident light, is formed, followed by a display circuit 26. On the surface of the second substrate 22 facing the liquid crystal layer 23, a display circuit 27 is formed. Thus, the liquid crystal display panel 20 is formed to be a reflective liquid crystal display panel having the reflecting layer 25 to reflect externally incident light.

Although not shown, the display circuits 26 and 27 include electrode layers made from transparent conductive layers and alignment layers that control alignment of the liquid crystal layer 23. In some cases, the display circuits 26 and 27 may include color filters to display colors.

To form the reflecting layer 25, the reflecting film 29 made from a metal film of high reflectance, such as aluminum or silver, is formed by sputtering on the organic film 28 which is made of acrylate resin and has irregularities on its surface. Additionally, a planarizing layer made of silicone resin may be formed over the reflecting film 29 and the organic film 28.

The reflecting layer 25 may include a color filter. In this case, the color filter is preferably disposed directly on the reflecting film 29. This structure allows the color filter to be disposed on a light reflecting surface and, therefore, can provide a high-quality display by decreasing color drift and parallax.

The front light 10 includes the light guide plate 12 and the light source 13. The light source 13 is mounted on the side surface 12a of the light guide plate 12 through which light enters the light guide plate 12. The light source 13 includes a rod light guide 13a mounted on the side surface 12a of the light guide plate 12 and light-emitting elements 13b attached to both ends of the rod light guide 13a. The rod light guide 13a can propagate light emitted from the light-emitting elements 13b towards the side surface 12a of the light guide plate 12. The light-emitting elements 13b may be light-emitting diodes, cold-cathode tubes, or organic electroluminescent elements. Alternatively, replacing the rod light guide 13a itself with a light-emitting diode, a cold-cathode tube, or an organic electroluminescent element can eliminate the light-emitting elements 13b.

The light guide plate 12 is disposed at the front of a display area (the display surface 20a) of the liquid crystal display panel 20 and illuminates the liquid crystal display panel 20 with light emitted from the light source 13. The light guide plate 12 includes a plate-like transparent body 12d. As shown in FIG. 2, the light source 13 is mounted on the side surface 12a of the body 12d. The light emitted from the light source 13 enters the interior of the body 12d through the side surface 12a. The other surface of the body 12d, namely, the surface facing the liquid crystal display panel 20 is an exit surface 12b, through which the light emerges to illuminate the liquid crystal display panel 20. The opposing surface of the exit surface 12b, namely, an outer surface of the light guide plate 12 is a reflecting surface 12c to change the direction of the light propagating in the interior of the body 12d. The entire exit surface 12b is in tight contact with the display surface 20a of the liquid crystal display panel 20.

The exit surface 12b outputs light for illuminating the liquid crystal display panel 20. The surface is so smooth that the roughness Ra of the exit surface 12b is less than or equal to 10 nm. On the reflecting surface 12c, a plurality of wedge-shaped grooves 14 are formed in a stripe pattern with a predetermined pitch to change the direction of the light propagating in the interior of the body 12d by reflection. The groove 14 has a gentle slope 14a inclined with respect to the exit surface 12b and a steep slope 14b, which is connected to the gentle slope 14a and has a larger slope angle than the gentle slope 14a. Each groove 14 is arranged in parallel to the side surface 12a of the light guide plate 12.

The resilient material of the body 12d of the light guide plate is preferably a rubber-like or jelly-like soft material, such as silicone resin or acrylate resin. The refractive index of the resilient material preferably ranges from 1.4 to 1.6. This range prevents reflection of light at the interface between the exit surface 12b and the display surface 20a of the liquid crystal display panel 20.

Since the body 12d of the light guide plate is made of the above-described resilient material, the exit surface 12b is flexibly deformed so that it is in tight contact with the display surface 20a by simply urging the light guide plate 12 onto the liquid crystal display panel 20. Accordingly, an air layer between the light guide plate 12 and the liquid crystal display panel 20 disappears and, therefore, light is not reflected by the exit surface 12b of the light guide plate 12. As a result, the luminance of the black display of the liquid crystal display panel 20 can be decreased, thus increasing the contrast, which is the luminance ratio of the white display to the black display.

That is, with reference to FIG. 3, light 16 emitted from a light source (not shown), which is positioned at the left side, propagates inside the body 12d while being reflected by the inner surface of the body 12d. Each groove 14 formed on the reflecting surface 12c consists of a gentle slope 14a and a steep slope 14b. The gentle slope 14a is inclined towards the propagation direction of the light, namely, the direction deviating from the light source, while the steep slope 14b is inclined towards the opposite direction of the gentle slope 14a.

In this structure, the light propagating inside the body 12d is reflected by the steep slope 14b towards the liquid crystal display panel 20, passes through the interface between the exit surface 12b and the display surface 20a, and enters the interior of the liquid crystal display panel 20. Then, the light passes through the liquid crystal layer 23 and is reflected by the reflector 25. The light passes through the liquid crystal layer 23 again, passes through the light guide plate 12, and then emerges from the light guide plate 12. In this case, light reflection by the exit surface 12b of the light guide plate 12 does not occur. Accordingly, the luminance of the black display of the liquid crystal display panel 20 can be decreased, thus increasing the contrast, which is the luminance ratio of the white display to the black display.

The slope angle θ₁ of the gentle slope 14a ranges from 1° to 5°, while the slope angle θ₂ of the steep slope 14b ranges from 40° to 45°. The pitch P_{T} of the grooves 14 ranges from 50 μm to 300 μm. These ranges of the slope angles θ₁ and θ₂ and the pitch P_{T} can further increase the contrast of the liquid crystal display device. Additionally, these ranges can make the intensity of the light emitted from the exit surface 12b uniform over the exit surface 12b. Also, a front light that does not generate a bright line on the reflecting surface 12c of the light guide plate 12 can be achieved.

Additionally, as described above, the light propagating inside the body 12d is reflected by the steep slope 14b towards the liquid crystal display panel 20. The light is gradually attenuated while propagating inside the body 12d. Therefore, in order to emit light having uniform intensity from the entire light guide plate 12, the reflecting area in the steep slope 14b that is distal to the light source is preferably larger than the reflecting area in the steep slope 14b that is proximal to the light source. In particular, in terms of the length of the steep slope 14b, which is the length in the direction perpendicular to the lengthwise direction of the groove 14, the length of the groove 14 distal to the light source is preferably longer than that of the groove 14 proximal to the light source. More specifically, the length of the steep slope 14b nearest to the light source is preferably about a half of that of the other steep slopes 14b. This structure of the light guide plate 12 allows the entire light guide plate 12 to emit light having uniform intensity and, therefore, provides a uniform contrast.

### Second Embodiment

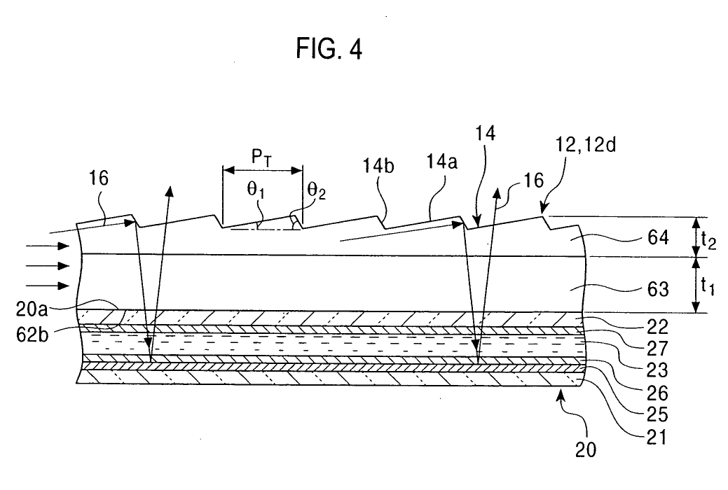

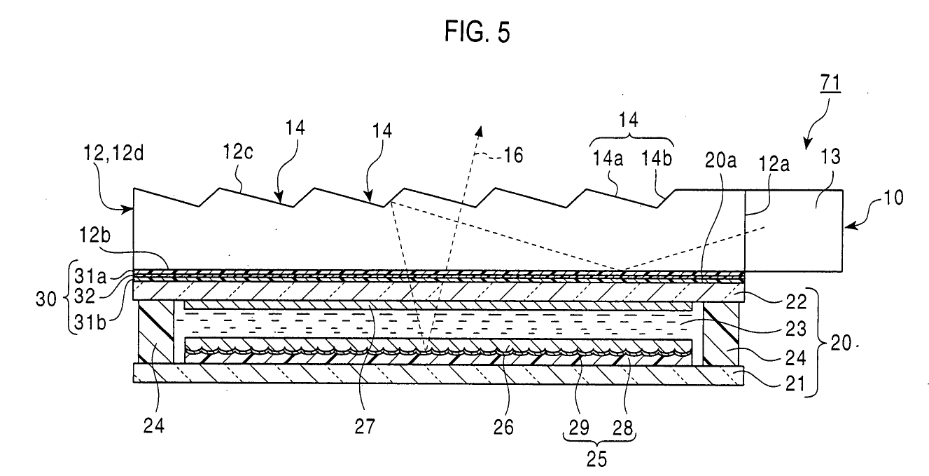

A second embodiment of the present invention will now be described with reference to the accompanying drawings. FIG. 4 is a schematic sectional view of a liquid crystal display device according to this embodiment. FIG. 5 is an enlarged schematic sectional view of a relevant portion of the liquid crystal display device shown in FIG. 4. FIGS. 4 and 5 are drawings only for explaining the structure of the liquid crystal display device and, therefore, the scales for the dimensions and thicknesses of the elements are different from the actual ones. In FIGS. 4 and 5, the elements identical to those illustrated and described in relation to FIGS. 1 to 3 are designated by like reference numerals, and the descriptions are omitted or briefly stated.

As shown in FIGS. 4 and 5, a liquid crystal display device 51 according to the embodiment includes a liquid crystal display panel 20 and a front light (surface light-emitting unit) 60, which is disposed on the display surface 20a of the liquid crystal display panel 20 to illuminate the liquid crystal display panel 20. The front light 60 includes a transparent light guide plate 62 and a light source 13. The light source 13 is mounted on a side surface 62a of the light guide plate 62, through which light enters the light guide plate 62.

The light guide plate 62 is made from a resilient material 63 and a hard material 64. The resilient material 63 has an exit surface 62b and the hard material 64 has a reflecting surface 62c. The exit surface 62b of the light guide plate 62 is in tight contact with the display surface 20a of the liquid crystal display panel 20.

The light guide plate 62, which constitutes the front light 60, is disposed at the front of a display area (the display surface 20a) of the liquid crystal display panel 20 and illuminates the liquid crystal display panel 20 with light emitted from the light source 13. The light guide plate 62 includes a plate-like transparent body 62d. As shown in FIG. 4, the light source 13 is mounted on the side surface 62a of the body 62d. The light emitted from the light source 13 enters the interior of the body 62d through the side surface 62a. The other surface of the body 62d, namely, the surface facing the liquid crystal display panel 20 is the exit surface 62b, through which the light emerges to illuminate the liquid crystal display panel 20. The opposing surface of the exit surface 62b, namely, an outer surface of the light guide plate 62, is the reflecting surface 62c to change the direction of the light propagating in the interior of the body 62d. The entire exit surface 62b is in tight contact with the display surface 20a of the liquid crystal display panel 20.

The exit surface 62b of the light guide plate 62 is in tight contact with the liquid crystal display panel 20 to output light for illuminating the liquid crystal display panel 20. The exit surface 62b is so smooth that the roughness Ra of the exit surface 62b is less than or equal to 10 nm. On the reflecting surface 62c, a plurality of wedge-shaped grooves 14 are formed in a stripe pattern with a predetermined pitch to change the direction of the light propagating in the interior of the body 12d by reflection. Each groove 14 has a gentle slope 14a inclined with respect to the exit surface 62b and a steep slope 14b, which is connected to the gentle slope 14a and has a larger slope angle than the gentle slope 14a. The grooves 14 are arranged in parallel to the side surface 62a of the light guide plate 62.

The body 62d of the light guide is made from the resilient material 63 having the exit surface 62b and the hard material 64 having the reflecting surface 62c. The hard material 64 is layered on the resilient material 63. The resilient material 63 may be made of, as in the first embodiment, transparent resin, such as silicone resin or acrylate resin. In this embodiment, since the hard material 64 is layered on the resilient material 63, the hard material 64 functions as a reinforcing material.

As well as acrylate resin, the hard material 64 may be transparent resin, such as polycarbonate resin or epoxy resin, or glass. Exemplary examples include, but are not limited to, ARTON (brand name) from JSR Corporation and ZEONOR (brand name) from ZEON Corporation.

Additionally, the degree of elasticity of the resilient material 63 is preferably smaller than that of the hard material 64. Further, the refractive index of the resilient material 63 preferably ranges from about 1.4 to 1.6. Also, the refractive index of the hard material 64 preferably ranges from about 1.4 to 1.6. The refractive indices of the resilient material 63 and the hard material 64 are preferably the same. This range of refractive index of the resilient material 63 can prevent reflection of light at the interface between the exit surface 62b and the display surface 20a of the liquid crystal display panel 20. The same refractive indices of the resilient material 63 and the hard material 64 can prevent reflection of light at the interface between the resilient material 63 and the hard material 64.

As shown in FIG. 5, the thickness t₁ of the resilient material 63 is preferably greater than the thickness t₂ of the hard material 64 (t₁>t₂). The resilient material 63 with a thickness greater than that of the hard material 64 can improve productivity when the light guide plate 62 is brought in tight contact with the liquid crystal display panel 20.

Since the exit surface 62b of the light guide plate 62 is made of the resilient material 63, the exit surface 62b is flexibly deformed so that it is in tight contact with the display surface 20a by simply urging the light guide plate 62 onto the liquid crystal display panel 20. Accordingly, an air layer between the light guide plate 62 and the liquid crystal display panel 20 disappears and, therefore, light is not reflected by the exit surface 62b of the light guide plate 62. As a result, the luminance of the black display of the liquid crystal display panel 20 can be decreased, thus increasing the contrast, which is the luminance ratio of the white display to the black display.

Additionally, the hard material 64 functions as a reinforcing material by laminating the hard material 64 on the resilient material 63. This facilitates the handling of the light guide plate 62, and the light guide plate 62 can be easily brought into tight contact with the liquid crystal display panel 20.

### Third Embodiment

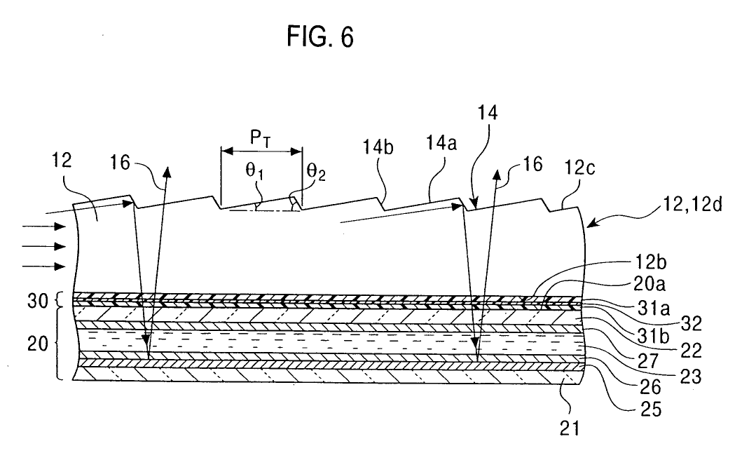

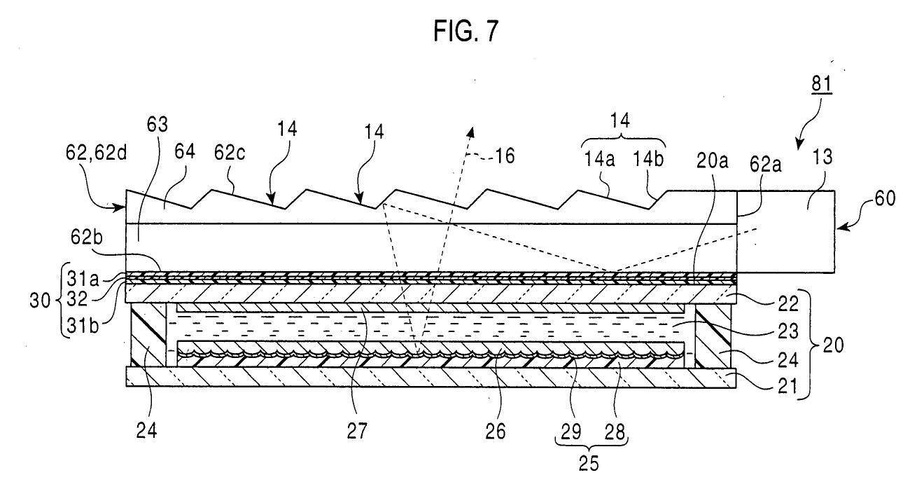

A third embodiment of the present invention will now be described with reference to the accompanying drawings. FIG. 6 is a schematic sectional view of a liquid crystal display device according to the embodiment. FIG. 7 is an enlarged schematic sectional view of a relevant portion of the liquid crystal display device shown in FIG. 6. FIGS. 6 and 7 are drawings only for explaining the structure of the liquid crystal display device and, therefore, the scales for the dimensions and thicknesses of the elements are different from the actual ones. In FIGS. 6 and 7, the elements identical to those illustrated and described in relation to FIGS. 1 to 3 are designated by like reference numerals, and the descriptions are omitted or briefly stated.

As shown in FIGS. 6 and 7, a liquid crystal display device 71 according to the embodiment includes a liquid crystal display panel 20, a front light (surface light-emitting unit) 10, which is disposed on the display surface 20a of the liquid crystal display panel 20 to illuminate the liquid crystal display panel 20. The liquid crystal display panel 20 is in tight contact with the front light 10 by a multi-layered adhesive layer 30.

The liquid crystal display panel 20 and the front light 10 are identical to those described in the first embodiment. The structures, the materials, and the refractive indices are also identical to those described in the first embodiment.

The adhesive layer 30 is composed of an adhesive transparent resin film 31a over the entire surface of the exit surface 12b of the light guide plate 12, another adhesive transparent resin film 31b over the display surface of the liquid crystal display panel 20, and an ultraviolet curable resin layer 32 between the adhesive transparent resin films 31a and 31b. By disposing the adhesive layer 30 between the light guide plate 12 and the liquid crystal display panel 20, the light guide plate 12 can be in tight contact with the liquid crystal display panel 20 without an air layer therebetween. In addition, each resin film 31a , 31b, or 32 of the adhesive layer 30 can be relatively thin and, therefore, bubbles do not occur in the layers. Accordingly, the exit surface 12b can be in tight contact with the display surface 20a, thus preventing reflection of light from the exit surface 12b of the light guide plate 12.

A material for the adhesive transparent resin films 31a and 31b is, for example, acrylate adhesive transparent resin. The refractive index of the adhesive transparent resin films 31a and 31b preferably ranges from 1.4 to 1.6. This range of the refractive index can prevent the occurrence of reflected light at the interfaces between the exit surface 12b and the adhesive transparent resin film 31a and between the display surface 20a and the adhesive transparent resin film 31b.

The material used for the ultraviolet curable resin layer 32 is, for example, acrylate UV-curable resin. The refractive index of the ultraviolet curable resin layer 32 preferably ranges from 1.4 to 1.6. This range of the refractive index can prevent the occurrence of reflected light at the interfaces between the adhesive transparent resin film 31a and the ultraviolet curable resin layer 32 and between the adhesive transparent resin film 31b and the ultraviolet curable resin layer 32. Further, the uncured ultraviolet curable resin layer 32 is preferably in fluid form, such as liquid. The uncured ultraviolet curable resin layer 32 in fluid form eliminates any possibility of bubbles remaining after the light guide plate 12 and the liquid crystal display panel 20 are bonded.

Furthermore, the thickness of each of the adhesive transparent resin films 31a and 31b is preferably smaller than or equal to 400 μm. The thickness of the ultraviolet curable resin layer 32 is preferably smaller than or equal to 100 μm and, in particular, smaller than the thickness of each of the adhesive transparent resin films 31a and 31b. The total thickness of the adhesive layer 30 preferably ranges from 0.2 mm to 0.8 mm. A total thickness smaller than or equal to 0.2 mm disadvantageously complicates the bonding work of the liquid crystal display panel 20 and the light guide plate 12. A total thickness greater than 0.8 mm increases the amount of absorbed light in the adhesive layer 30 itself and, therefore, the luminance is sometimes non-uniform, which is a problem.

### Fourth Embodiment

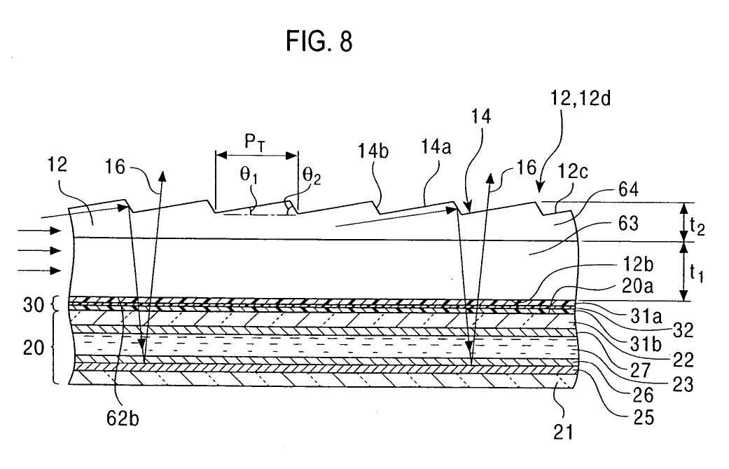

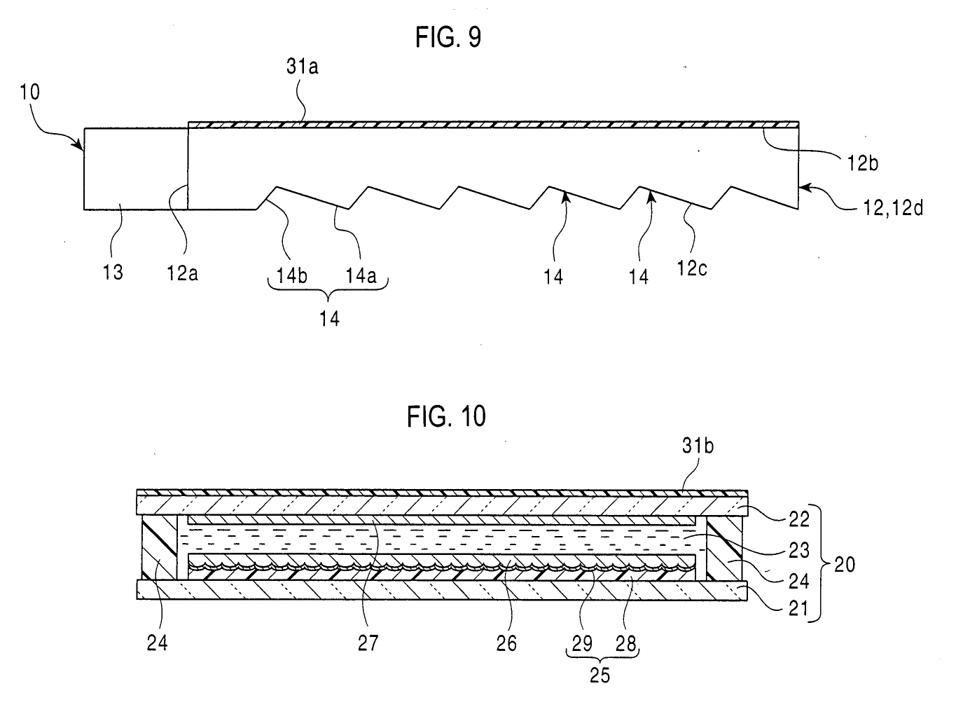

A fourth embodiment of the present invention will now be described with reference to the accompanying drawings. FIG. 8 is a schematic sectional view of a liquid crystal display device according to this embodiment. FIG. 9 is an enlarged schematic sectional view of a relevant portion of the liquid crystal display device shown in FIG. 8. FIGS. 8 and 9 are drawings only for explaining the structure of the liquid crystal display device and, therefore, the scales for the dimensions and thicknesses of the elements are different from the actual ones. In FIGS. 8 and 9, the elements identical to those illustrated and described in relation to FIGS. 1 to 5 are designated by like reference numerals, and the descriptions are omitted or briefly stated.

As shown in FIGS. 8 and 9, a liquid crystal display device 81 includes a liquid crystal display panel 20 and a front light (surface light-emitting unit) 60, which is disposed on the display surface 20a of the liquid crystal display panel 20 to illuminate the liquid crystal display panel 20. The liquid crystal display panel 20 is in tight contact with the front light 60 by a multi-layered adhesive layer 30.

The liquid crystal display panel 20 and the front light 60 are identical to those described in the second embodiment. The structures, the materials, and the refractive indices are also identical to those described in the second embodiment.

The adhesive layer 30 is composed of an adhesive transparent resin film 31a over the entire exit surface 62b of a light guide plate 62, another adhesive transparent resin film 31b over the display surface of the liquid crystal display panel 20, and an ultraviolet curable resin layer 32 between the adhesive transparent resin films 31a and 31b. By disposing the adhesive layer 30 between the light guide plate 62 and the liquid crystal display panel 20, the light guide plate 62 can be in tight contact with the liquid crystal display panel 20 without an air layer therebetween. In addition, each resin film 31a, 31b, or 32 of the adhesive layer 30 can be relatively thin and, therefore, bubbles do not occur in the films. Accordingly, the exit surface 62b can be in tight contact with the display surface 20a, thus preventing the occurrence of reflected light at the exit surface 62b of the light guide plate 62.

The material, the refractive indices, and the thicknesses of the adhesive transparent resin films 31a and 31b are identical to those described in the third embodiment. Also, the material and the refractive index of the ultraviolet curable resin layer 32 are identical to those described in the third embodiment.

### Fifth Embodiment

A method for manufacturing a liquid crystal display device, which is a fifth embodiment of the present invention, will now be described with reference to the accompanying drawings. FIGS. 10 to 13 show cross-sectional views of a liquid crystal display device in the fabrication steps according to the embodiment. In this embodiment, the liquid crystal display device shown in the third embodiment is taken as an example.

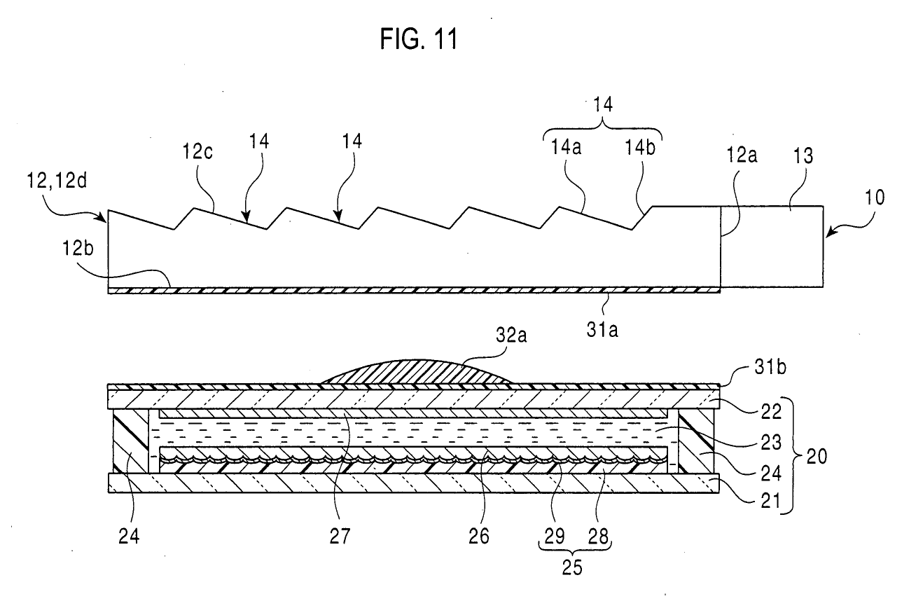

As shown in FIG. 10, the adhesive transparent resin film 31a is formed over the entire exit surface 12b of the light guide plate 12. Also, as shown in FIG. 11, the adhesive transparent resin film 31b is formed over the display surface 20a of the liquid crystal display panel 20. The thicknesses of the adhesive transparent resin films 31a and 31b are preferably smaller than or equal to 400 μm.

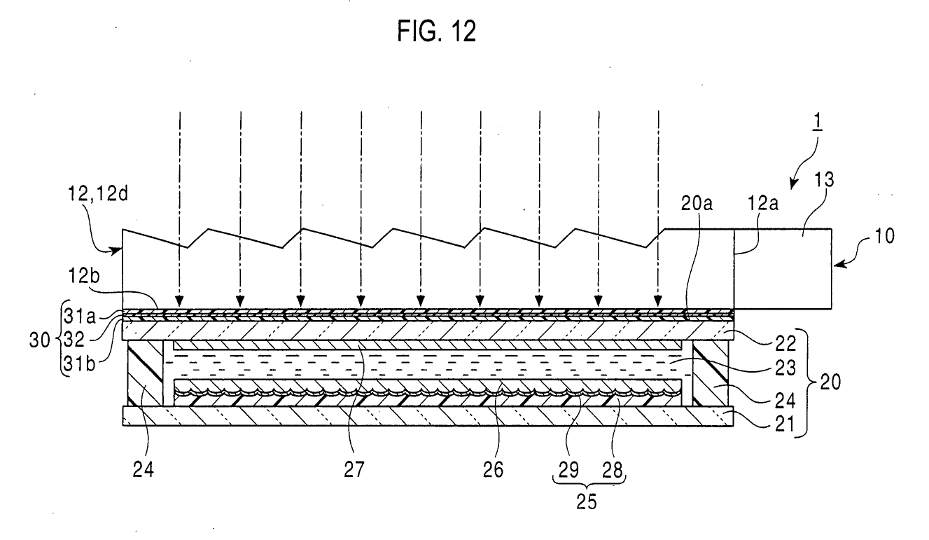

With reference to FIG. 12, uncured ultraviolet curable resin 32a is thickly applied to the adhesive transparent resin film 31b, which is on the liquid crystal display panel 20 side, at substantially the center of the display surface 20a. The method of applying the ultraviolet curable resin 32a is not limited to that in the drawing; the ultraviolet curable resin layer 32 may be applied to the entire display surface 20a uniformly. Alternatively, the ultraviolet curable resin 32a may be applied to either the center of the exit surface 12b of the light guide plate 12 thickly or to the entire exit surface 12b of the light guide plate 12 uniformly. Additionally, the ultraviolet curable resin 32a may be applied to both the light guide plate 12 and the liquid crystal display panel 20. The ultraviolet curable resin 32a is preferably in the form of fluid, such as liquid.

With reference to FIG. 13, the exit surface 12b of the light guide plate 12 is bonded to the display surface 20a of the liquid crystal display panel 20. During bonding, the ultraviolet curable resin 32a spreads over the entire surfaces of the adhesive transparent resin films 31a and 31b so that an air layer (bubbles) is completely expelled from between the light guide plate 12 and the liquid crystal display panel 20.

Subsequently, as shown in FIG. 13, ultraviolet rays are irradiated on the ultraviolet curable resin 32a. As shown by a chain line in FIG. 13, the ultraviolet rays are emitted from outside of the reflecting surface 12c of the light guide plate 12. The ultraviolet rays pass through the light guide plate 12, and then the ultraviolet curable resin 32a is irradiated with the ultraviolet rays so that the ultraviolet curable resin 32a is cured to form the ultraviolet curable resin layer 32. At the same time, the ultraviolet curable resin layer 32 is tightly bonded to the adhesive transparent resin films 31a and 31b. Thus, the light guide plate 12 is joined with the liquid crystal display panel 20 to achieve the liquid crystal display device 71 shown in the third embodiment.

According to the above-described method for fabricating a liquid crystal display device, the light guide plate 12 can be easily brought into tight contact with the liquid crystal display panel 20 without an air layer remaining in the interior of the adhesive layer 30 by irradiating ultraviolet rays on the ultraviolet curable resin 32a spread between the entire surfaces of the adhesive transparent resin films 31a and 31b.

1. A light guide plate comprising:
a plate member;
a reflecting surface on one side of the plate member for reflecting light propagating inside the plate member; and
an exit surface on an opposite side of the plate member for outputting the light reflected by the reflecting surface;
wherein at least the exit surface comprises a resilient material.

2. The light guide plate according to claim 1, wherein the entire plate member comprises a resilient material.

3. The light guide plate according to claim 1, wherein the plate member comprises a laminate of a resilient material and a hard material, the exit surface is disposed on a resilient material side, and the reflecting surface is disposed on a hard material side.

4. The light guide plate according to claim 1, wherein the reflecting surface has a series of grooves in a propagation direction of the light, each groove has a gentle slope inclined towards the propagation direction of the light and a steep slope which is inclined towards opposite to the propagation direction of the light and which has a larger slope angle than that of the gentle slope, a slope angle θ₁ of the gentle slope ranges from 1° to 5°, a slope angle θ₂ of the steep slope ranges from 40° to 45°, and a pitch of the grooves ranges from 50 μm to 300 μm.

5. A surface light-emitting unit, comprising:
the light guide plate according to claim 1; and
a light source disposed on a side surface of the light guide plate for emitting light into an interior of the light guide plate through the side surface.

6. A liquid crystal display device comprising:
a liquid crystal display panel having a display surface; and
a surface light-emitting unit on the display surface comprising a light source and a light guide plate for introducing light emitted from the light source into an interior of the light guide plate and outputting the light from an exit surface thereof;
wherein at least the exit surface comprises a resilient material and the exit surface is in tight contact with the display surface of the liquid crystal display panel.

7. The liquid crystal display device according to claim 6, wherein the light guide plate has a reflecting surface for reflecting light propagating inside the light guide plate and an exit surface opposite to the reflecting surface for outputting the light reflected by the reflecting surface.

8. The liquid crystal display device according to claim 6, wherein the entire light guide plate comprises a resilient material.

9. The liquid crystal display device according to claim 6, wherein the light guide plate comprises a laminate of a resilient material and a hard material, the exit surface is disposed on a resilient material side, and the reflecting surface is disposed on a hard material side.

10. The liquid crystal display device according to claim 6, wherein the reflecting surface has a series of grooves in a propagation direction of the light, each groove has a gentle slope inclined towards the propagation direction of the light and a steep slope which is inclined towards opposite to the propagation direction of the light and which has a larger slope angle than that of the gentle slope, a slope angle θ₁ of the gentle slope ranges from 1° to 5°, a slope angle θ₂ of the steep slope ranges from 40° to 45°, and a pitch of the grooves ranges from 50 μm to 300 μm.

11. A liquid crystal display device comprising:
a liquid crystal display panel having a display surface; and
a surface light-emitting unit on the display surface comprising a light source and a light guide plate for introducing light emitted from the light source into an interior of the light guide plate and outputting the light from an exit surface thereof;
wherein, the exit surface is in tight contact with the display surface by an adhesive layer, and the adhesive layer comprises an adhesive transparent resin film layered on the exit surface, another adhesive transparent resin film layered on the display surface, and an ultraviolet-curable resin layer between the adhesive transparent resin films.

12. The liquid crystal display device according to claim 11, wherein at least the exit surface of the light guide plate comprises a resilient material.

13. The liquid crystal display device according to claim 11, wherein the light guide plate has a reflecting surface for reflecting light propagating inside the light guide plate and an exit surface opposite to the reflecting surface for outputting the light reflected by the reflecting surface.

14. The liquid crystal display device according to claim 11, wherein the entire light guide plate comprises a resilient material.

15. The liquid crystal display device according to claim 11, wherein the light guide plate comprises a laminate of a resilient material and a hard material, the exit surface is disposed on a resilient material side, and the reflecting surface is disposed on a hard material side.

16. The liquid crystal display device according to claim 11, wherein the reflecting surface has a series of grooves in a propagation direction of the light, each groove has a gentle slope inclined towards the propagation direction of the light and a steep slope which is inclined towards opposite to the propagation direction of the light and which has a larger slope angle than that of the gentle slope, a slope angle θ₁ of the gentle slope ranges from 1° to 5°, a slope angle θ₂ of the steep slope ranges from 40° to 45°, and a pitch of the grooves ranges from 50 μm to 300 μm.

17. A method for attaching a surface light-emitting unit to a liquid crystal display panel, the surface light-emitting unit comprising a light source and a light guide plate having an exit surface for outputting light emitted from the light source and introduced into an interior of the light guide plate, the method comprising:
forming an adhesive transparent resin film on the exit surface;
forming another adhesive transparent resin film on a display surface of the liquid crystal display panel;
applying a fluid uncured-ultraviolet curable resin to at least one surface of the adhesive transparent resin films to form an uncured-ultraviolet curable resin layer;
bonding the exit surface to the display surface with the adhesive transparent resin films and the ultraviolet curable resin layer between the adhesive transparent resin films; and
curing the ultraviolet curable resin layer by irradiating the ultraviolet curable resin layer through the light guide plate with ultraviolet rays.
